(19) United States
(12) Patent Application Publication
(10) Pub. No.: US 2015/0345041 A1
(43) Pub. Date: Dec. 3, 2015

(54) IRON STRIKE PLATING ON CHROMIUM-CONTAINING SURFACES

(71) Applicant: Arcanum Alloy Design, Inc., Sunnyvale, CA (US)

(72) Inventors: Ersan Ilgar, Sunnyvale, CA (US); Daniel E. Bullard, Sunnyvale, CA (US)

(21) Appl. No.: 14/716,358

(22) Filed: May 19, 2015

Related U.S. Application Data
(60) Provisional application No. 62/004,844, filed on May 29, 2014.

(51) Int. Cl. C25D 5/00; C25D 3/20; C23C 28/02; C23F 17/00; C23C 16/06; C23C 16/56

(52) U.S. Cl. CPC C25D 5/00; C23C 16/06; C23C 16/56; C23C 28/021; C23F 17/00; C25D 3/20

(57) ABSTRACT

The present disclosure provides materials that include a stainless steel layer with a consistent or substantially consistent composition diffusion bonded to a carbon steel substrate. The material can have the corrosion resistance associated with the explosively welded stainless steel and the deep diffusion bonding observed typical of chromizing applications. In some embodiments, the disclosure provides materials having metal layers deposited onto a chromium surface and methods for depositing metal layers onto chromium surfaces. The present disclosure recognizes certain advantages to depositing metal layers onto chromium, such as more rapid diffusion of metals when heated to provide a stainless steel layer.

### CROSS-REFERENCE

This application claims priority to U.S. Provisional Patent Application No. 62/004,844, filed May 29, 2014, which application is herein incorporated by reference in its entirety for all purposes.

### BACKGROUND

Steel can be an alloy of iron and other elements, including carbon. When carbon is the primary alloying element, its content in the steel may be between 0.002% and 2.1% by weight. Without limitation, the elements carbon, manganese, phosphorus, sulfur, silicon, and traces of oxygen, nitrogen and aluminum can be present in steel. Alloying elements added to modify the characteristics of steel can include without limitation, manganese, nickel, chromium, molybdenum, boron, titanium, vanadium and niobium.

Stainless steel can be a material that does not readily corrode, rust (or oxidize) or stain with water. There can be different grades and surface finishes of stainless steel to suit a given environment. Stainless steel can be used where both the properties of steel and resistance to corrosion are beneficial.

### SUMMARY

In an aspect, the present disclosure provides a protective coating for steel. In some cases, a non-stainless steel product is metallurgically bonded to and carrying a stainless steel outer layer. The stainless steel outer layer can be formed by alternatively depositing metal layers onto a substrate (e.g., where the layers comprise the elements of stainless steel such as iron, nickel and chromium) and heating the metal layers such that the metal layers mix (e.g., by diffusion) to create a stainless steel layer metallically bonded to the substrate.

Previous methods for producing metallurgically bonded stainless steel may be limited with regard to the order of metal layers deposited on the substrate. It has not been previously possible to deposit metals onto a chromium surface with adequate adhesion to the chromium surface. This can limit chromium to being an outer-most metal layer.

The present disclosure recognizes certain advantages to depositing metal layers onto chromium, such as more rapid diffusion of metals when heated to provide a stainless steel layer. The present disclosure provides methods for depositing metals onto chromium and materials having a metal layer deposited onto chromium.

In an aspect, the present disclosure provides a method for plating iron on a chromium surface. The method can include providing a metal substrate having a surface; contacting the surface with a solution comprising hydrochloric acid (HCl) and an iron salt; and applying a voltage difference between the metal substrate and the solution, whereby a layer of iron is deposited on the surface. In some cases, the surface can include any one of chromium, titanium, or stainless steel. In some cases, the surface can be a passive surface. In some cases, the surface may include at least about 80%, at least about 90%, at least about 95%, at least about 99%, or at least about 99.9% chromium as measured by x-ray photoelectron spectroscopy (XPS). In some cases, the surface may include at least about 95% chromium as measured by XPS. In some cases, the substrate may comprise stainless steel.

In some cases, the layer of iron may have a thickness of about 0.5 μm, about 1 μm, about 1.5 μm, about 2 μm, about 3 μm, about 5 μm, or about 10 μm. In some cases, the layer of iron has a thickness of less than about 0.1 micrometer (μm), less than about 0.5 μm, less than about 1 μm, less than about 1.5 μm, less than about 2 μm, less than about 3 μm, less than about 5 μm, or less than about 10 μm. In some cases, the layer of iron may have a thickness of less than about 1 micrometer (μm).

In some cases, the method further comprises depositing an additional layer of metal on the layer of iron. An additional layer of iron can be deposited on the layer of iron, and nickel can be deposited on the additional layer of iron. In some cases, the additional layer of iron can be deposited without contacting the metal substrate with the solution. In some cases, the method can include heating the metal substrate, the layer of iron, and the additional layer of metal. The metal substrate, layer of iron and the additional layer of metal can be heated to a temperature of between about 930° C. and 1150° C.

In some cases, the method can include removing oil from the surface prior to contacting the surface with the solution. In some cases, the metal substrate can comprise carbon steel. In some cases, the surface can comprise an oxide of chromium and the solution dissolves the oxide of chromium from the surface.

In some cases, the solution can have between about 50 and about 300 grams of iron salt per liter of solution (g/L) and/or be at ambient temperature. In some cases, the iron salt can comprise ferrous ions (Fe²⁺). In some cases, the iron salt can comprise an iron halide. In some cases, the iron salt can comprise a chloride or sulfate salt. In some cases, the concentration of hydrochloric acid (HCl) can be between about 3 Normal (N) and 6 N. In some cases, applying the voltage difference can produce an electric current between about 50 amperes per square foot (Amp/ft²) and about 200 Amp/ft². In some cases, applying the voltage difference is performed for a period of time between about 20 seconds (s) and about 60 s. In some cases, the layer of iron adheres to the surface by metallic bonding. In some cases, contacting the surface with the solution and applying the voltage difference can be performed simultaneously.

In another aspect, the present disclosure provides a method for making a stainless steel surface diffusion bonded to a metal substrate. The method includes providing a metal substrate; depositing a layer of chromium adjacent to the metal substrate; depositing a layer of iron adjacent to the layer of chromium; depositing a layer of nickel adjacent to the layer of iron; and (e) heating the layers of chromium, iron and nickel to form a layer of stainless steel diffusion bonded to the metal substrate.

In some cases, the layer of chromium is deposited on the metal substrate. In some cases, the layer of iron is deposited on the layer of chromium. In some cases, the layer of nickel is deposited on the layer of iron. In some cases, at least one layer of iron comprises at least two layers of iron.

In some cases, depositing the at least one layer of iron adjacent to the layer of chromium includes (i) depositing a first layer of iron on the chromium and (ii) depositing an additional layer of iron on the first layer of iron. In some cases, the first layer of iron has a thickness of about 0.5 μm, about 1 μm, about 1.5 μm, about 2 μm, about 3 μm, about 5 μm, or about 10 μm. In some cases, the first layer of iron has a thickness of less than about 0.1 micrometer (μm), less than about 0.5 μm, less than about 1 μm, less than about 1.5 μm, less than about 2 μm, less than about 3 μm, less than about 5 μm, or less than about 10 μm. In some cases, the first layer of iron may have a thickness of less than about 1 micrometer (μm). In some cases, the first layer of iron has a thickness of less than about 1 micrometer (μm). In some cases, the first layer of iron can be deposited by contacting the chromium with a solution comprising hydrochloric acid (HCl) and iron and applying a voltage difference between the metal substrate and the solution, whereby the first layer of iron is deposited on the chromium. The iron can comprise an iron salt.

In some cases, depositing the layer of chromium adjacent to the metal substrate; depositing the at least one layer of iron adjacent to the layer of chromium; and depositing the layer of nickel adjacent to the layer of iron can be performed using electro-deposition or vapor deposition. In some cases, the layers of chromium, iron and nickel may be heated to a temperature between about 930° C. and 1150° C. The layers of chromium, iron and nickel can be heated for between about 15 hours (h) and about 20 h.

In some cases, the layer of stainless steel is at least about 50 microns (μm), at least about 100 μm, at least about 150 μm, at least about 200 μm, at least about 250 μm, at least about 300 μm, at least about 400 μm, at least about 500 μm, or at least about 1000 μm thick. In some cases, the layer of stainless steel is at least about 250 microns μm in thickness.

In another aspect, the present disclosure provides a material comprising: (a) a metal substrate; (b) a first metal layer comprising chromium deposited adjacent to the metal substrate; and (c) a second metal layer comprising iron deposited on the first metal layer.

In another aspect, the present disclosure provides a method for forming a material stack. The method includes providing a metal substrate, which can be a carbon or low-carbon steel substrate; depositing a first metal layer comprising chromium adjacent to the metal substrate; and depositing a second metal layer comprising iron on the first metal layer to form the material stack. The method elements of providing the metal substrate, depositing the first metal layer and depositing the second metal layer can be performed without annealing. Moreover, following completion of these elements, the material stack can be annealed.

In some cases, the first metal layer is deposited on the metal substrate. In some cases, the first metal layer comprises at least about 70%, at least about 75%, at least about 80%, at least about 85%, at least about 90%, at least about 91%, at least about 92%, at least about 93%, at least about 94%, at least about 95%, at least about 96%, at least about 97%, at least about 98% or at least about 99% chromium as measured by XPS. In some cases, the first metal layer comprises at least about 95% chromium as measured by XPS.

In some cases, the second metal layer has a thickness of 20 micrometers, 15 micrometers, 10 micrometers, 8 micrometers, 7 micrometers, 6 micrometers, 5 micrometers, 4 micrometers, 3 micrometers, 2 micrometers, 1 micrometer, 0.5 micrometer, 0.1 micrometer or less. In some cases, the second metal layer has a thickness of less than about 1 micrometer. In some cases, the second metal layer is metallically bonded to the first metal layer.

In some cases, the method can include depositing a third metal layer (e.g., comprising iron) on the second metal layer. In some cases, the method can include depositing a fourth metal layer (e.g., comprising nickel) on the third metal layer.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications and patent applications mentioned in this specification are herein incorporated by reference to the same extent as if each individual publication or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Fig.” and “Figs.” herein), of which:

FIG. 1A is an example of a metal sheet having a stainless steel surface metallurgically bonded to a carbon steel core;

FIG. 1B is an example of a metal rod having a stainless steel surface metallurgically bonded to a carbon steel core;

FIG. 2 shows an example of the approximate weight percentages of chromium and nickel as a function of depth for a 300 series stainless steel surface metallurgically bonded to a carbon steel core;

FIG. 3 shows an example of metal layers deposited on a carbon steel substrate; and

FIG. 4 shows an example of a ternary phase diagram for stainless steel.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “admixture,” as used herein in the context of a plurality of metals (e.g., transition metals), generally refers to a region in which metals are intermixed. An admixture can be a solid solution, an alloy, a homogeneous admixture, a heterogeneous admixture, a metallic phase, or one of the preceding further including an intermetallic or insoluble structure, crystal, or crystallite. In some cases, an admixture excludes intermixed grains or crystals or inter-soluble materials. Some admixtures may not include distinguishable grains of compositions that can form a solid solution or a single metallic phase (e.g., by heating the admixture to a temperature where the grains of compositions can inter-diffuse). In some cases, an admixture can include intermetallic species as these intermetallic species may not be soluble in the “solute” or bulk metallic phase. Furthermore, the exclusion of intermixed-intersoluble materials does not limit the homogeneity of the sample. A heterogeneous admixture can include a concentration gradient of at least one of the metals in the admixture, but may not include distinguishable grains or crystals of one phase or composition intermixed with grains, with crystals, or in a solute having a second phase of composition in which the first phase of composition is soluble.

The noun “alloy,” as used herein, generally refers to a composition of a plurality of metals. An alloy can be a specific composition of metals, e.g., transition metals, with a narrow variation in concentration of the metals throughout the admixture. One example of an alloy is 304 stainless steel that can have an iron composition that includes about 18-20 wt. % chromium (Cr), about 8-10.5 wt. % nickel (Ni), and about 2 wt. % manganese (Mn). As used herein, an alloy that occupies a specific volume may not include a concentration gradient. Such a specific volume that includes a concentration gradient can include, as an admixture, a plurality or range of alloys.

The term “concentration gradient,” as used herein, generally refers to the regular increase or decrease in the concentration of at least one element in an admixture. In some cases, a concentration gradient is observed in an admixture where at least one element in the admixture increases or decreases from a set value to a higher/lower set value. The increase or decrease can be linear, parabolic, Gaussian, or mixtures thereof. In some cases, a concentration gradient is not a step function. A step function variation can be described as a plurality of abutting admixtures.

The term “adjacent” or “adjacent to,” as used herein, includes ‘next to’, ‘adjoining’, ‘in contact with’, and ‘in proximity to’. In some instances, adjacent to components are separated from one another by one or more intervening layers. For example, the one or more intervening layers can have a thickness less than about 10 micrometers (“microns”), 1 micron, 500 nanometers (“nm”), 100 nm, 50 nm, 10 nm, 1 nm, or less. In an example, a first layer is adjacent to a second layer when the first layer is in direct contact with the second layer. In another example, a first layer is adjacent to a second layer when the first layer is separated from the second layer by a third layer.

Layers and/or regions of the materials can be referred to as being “metallurgically bonded.” That is, the metals, alloys or admixtures that provide the composition of the layers and/or regions can be joined through a conformance of lattice structures. Intermediate layers such as adhesives or braze metal are not necessarily involved. Bonding regions can be the areas in which the metallurgical bonds between two or more metals, alloys or admixtures display a conformance of lattice structures. The conformance of lattice structures can include the gradual change from the lattice of one metal, alloy or admixture to the lattice of the metallurgically bonded metal, alloy or admixture.

While terms used herein may be commonly used in the steel industry, the compositions or regions may comprise, consist of, or consist essentially of, one or more elements. In some cases, steel is considered to be carbon steel (e.g., a mixture of at least iron, carbon, and up to about 2% total alloying elements). Alloying elements or alloying agents can include, but are not limited to, carbon (C), chromium (Cr), cobalt (Co), niobium (Nb), molybdenum (Mo), nickel (Ni), titanium (Ti), tungsten (W), vanadium (V), zirconium (Zr) or other metals. In some cases, steel or carbon steel can be a random composition of a variety of elements supported in iron. When compositions or regions are described as consisting of, or consisting essentially of, one or more elements, the concentration of non-disclosed elements in the composition or region may not detectable by energy-dispersive X-ray spectroscopy (EDX) (e.g., EDX can have a sensitivity down to levels of about 0.5 to 1 atomic percent). When the composition or region is described as consisting of one or more elements, the concentration of the non-disclosed elements in the composition or region may not be detectable or within the measurable error of direct elemental analysis, e.g., by inductively coupled plasma (ICP).

The articles “a”, “an” and “the” are non-limiting. For example, “the method” includes the broadest definition of the meaning of the phrase, which can be more than one method.

The present disclosure provides methods for protecting steel. In some embodiments, a method for protecting steel includes providing one or more stainless steel compositions on the exterior of the steel product. The product can be pre-fabricated into a given shape, such as, for example, an electronic component (e.g., phone, computer) or mechanical component (e.g., fixture). Chromizing can be a common method for the production of chromium-iron alloys (e.g., stainless steels) on the surface of steels. Chromizing steel can involve a thermal deposition-diffusion processes whereby chromium can diffuse into the steel and produce a varying concentration of chromium in the steel substrate. In some cases, the surface of the substrate has the highest chromium concentration and the chromium concentration decreases as the distance into the substrate increases. In some cases, the chromium concentration follows a diffusion function (e.g., the chromium concentration decreases exponentially as a function of distance from the substrate). Other chromizing products (e.g., as described in U.S. Pat. No. 3,312,546, which is entirely incorporated herein by reference) can include diffusion coatings that have chromium concentrations above 20% that decrease linearly as a function of distance into the substrate. These high chromium-content coatings can appear to include a foil or layer of chromium containing material carried by the bulk substrate.

The decreasing concentration of chromium as a function of depth into the substrate can affect the corrosion resistance of the material. In some cases, abrasion of the surface continuously produces new layers with lower chromium concentrations that are less corrosion resistant than the initial surface. This undesirable effect can be due to the variable concentration of chromium in the chromized surfaces.

Explosive welding or cladding of stainless steel onto a carbon steel or low-carbon steel can produce a stainless steel layer with a consistent composition metallurgically bonded to a carbon steel substrate. This technique can overcome the variable concentrations associated with chromizing, but can be limited by the thicknesses of the flying layer, the use of high explosives, and/or the metallurgical bond that is formed. At least two types of metallurgical bonds can be observed in explosively welding metals. Under high explosive loading, the cross-section can be composed of a wave-like intermixing of the base and flying layers and under lower explosive loadings the cross-section can include an implantation of grains of the flying layer into the base layer (e.g., see Explosive welding of stainless steel-carbon steel coaxial pipes, J. Mat. Sci., 2012, 47-2, 685-695, and Microstructure of Austenitic stainless Steel Explosively Bonded to low Carbon-Steel, J. Electron Microsc. (Tokyo), 1973, 22-1, 13-18, each of which are incorporated by reference in its entirety).

In an aspect, the present disclosure provides a material that includes a stainless steel layer with a consistent composition diffusion bonded to a carbon steel substrate. The material can have the corrosion resistance associated with the explosively welded stainless steel and the deep diffusion bonding observed typical of chromizing applications.

An aspect of the present disclosure provides materials comprising an outer metal layer metallurgically bonded to a steel substrate. The substrate can be a carbon steel or low-carbon steel substrate. The outer metal layer can be formed by any one or more of a variety of methods. In some cases, the outer metal layer is formed by vapor deposition (e.g., chemical vapor deposition (CVD), physical vapor deposition (PVD), atomic layer deposition (ALD), and/or plasma-enhanced CVD (PECVD)). In some instances, the outer material layer is formed by electrochemical deposition (e.g., electroplating). Electroplating can use electrical current to reduce dissolved metal cations so that they form a metal coating on an electrode. Examples of methods suitable for the formation of an outer metal layer are described in U.S. patent application Ser. No. 13/629,699; U.S. patent application Ser. No. 13/799,034; and U.S. patent application Ser. No. 13/800,698, each of which is incorporated herein by reference in its entirety.

The material described here can include a variety of metallurgically bonded metals, alloys or admixtures. In some cases, the materials have a certain composition or concentration and/or variation of the compositions or concentrations as a function of depth or distance through the material (e.g., of transition metals in the metals, alloys or admixtures). In some cases, the composition or concentrations of the component metals in the metals, alloys or admixtures can be determined by energy-dispersive X-ray spectroscopy (EDX). In some instances, when a composition is described as being “approximately consistent” over a distance, in a layer, or in a region, the term means that the relative percentage of metals in that distance, layer or region is consistent within the standard error of measurement by EDX. In some cases, the moving average over the “approximately consistent” distance, layer or region has a slope of about zero when plotted as a function of concentration (y-axis) to distance (x-axis). In some instances, the concentration (or relative percentage) of the individual elements in the composition vary by less than about 5 wt. %, 4 wt. %, 3 wt. %, 2 wt. %, or 1 wt. % over the distance.

In some embodiments, the present disclosure provides a steel form having a stainless steel exterior. The steel form can include a core region which carries a stainless steel coating (e.g., the steel form includes the core region, a bonding region, and a stainless steel region, where the bonding region metallurgically bonds the core region to the stainless steel region). In some cases, the steel form is defined by layers or regions that can include at least 55 wt. % iron (e.g., the steel form can be coated by organic or inorganic coatings but these coatings are not considered part of the steel form). In some cases, the core region of the steel form can include iron (e.g., at least 55 wt. % iron). In some instances, the iron concentration in the core region is greater than 98 wt. %, 99 wt. %, or 99.5 wt. %. In some embodiments, the core region can be a carbon steel having a carbon concentration of less than about 0.5 wt. %. In some cases, the core region is a carbon steel having a carbon concentration of less than about 0.25 wt. %. In some embodiments, the core region is substantially free of chromium and/or substantially free of nickel.

The stainless steel coating carried by (i.e., disposed upon) the core region can consist of a stainless steel region and a bonding region. In some cases, the bonding region can be proximal to the core region and the stainless steel region including the stainless steel exterior. The stainless steel region can have a thickness of about 1 μm to about 250 μm, about 5 μm to about 250 μm, about 10 μm to about 250 μm, about 25 μm to about 250 μm, about 50 μm to about 250 μm, about 10 μm to about 200 μm, or about 10 μm to about 100 μm.

The stainless steel region can have a stainless steel composition. As used here, a “stainless steel composition” means that the stainless steel region includes an admixture of iron and chromium. In some cases, the stainless steel composition includes a chromium concentration of about 10 wt. % to about 30 wt. % (e.g., about 10 wt. %, about 12 wt. %, about 14 wt. %, about 16 wt. %, about 18 wt. %, about 20 wt. %, about 22 wt. %, about 24 wt. %, about 26 wt. %, about 28 wt. %, or about 30 wt. %). In some cases, the stainless steel composition is approximately consistent across the thickness of the stainless steel region.

In some embodiments, in an approximately or substantially consistent stainless steel composition, the relative percentage of metals in that distance layer or region is consistent within the standard error of measurement by energy-dispersive X-ray spectroscopy (EDX). For instance, the moving average over the approximately or substantially consistent distance, layer or region has a slope of about zero when plotted as a function of concentration (y-axis) to distance (x-axis). In some embodiments, the concentration (or relative percentage) of the individual elements in the composition vary by less than about 40 wt. %, 30 wt. %, 20 wt. %, 15 wt. %, 10 wt. %, 9 wt. %, 8 wt. %, 7 wt. %, 6 wt. %, 5 wt. %, 4 wt. %, 3 wt. %, 2 wt. %, or 1 wt. % over the distance. In some cases, the concentration (or relative percentage) of the individual elements in the composition vary by less than about 40 wt. %, 30 wt. %, 20 wt. %, 15 wt. %, 10 wt. %, 9 wt. %, 8 wt. %, 7 wt. %, 6 wt. %, 5 wt. %, 4 wt. %, 3 wt. %, 2 wt. %, or 1 wt. % over a distance (e.g., depth) of at least about 10 nanometers (nm), 20 nm, 30 nm, 40 nm, 50 nm, 60 nm, 70 nm, 80 nm, 90 nm, 100 nm, 200 nm, 300 nm, 400 nm, 500 nm, 1 micrometer (micron), 2 microns, 3 microns, 4 microns, 5 microns, 10 microns, 20 microns, 30 microns, 40 microns, 50 microns, 100 microns, 200 microns, 300 microns, 400 microns, or 500 microns.

The stainless steel composition can include an admixture of iron and chromium, and can further include a transition metal selected from the group consisting of nickel, molybdenum, titanium, niobium, tantalum, vanadium, tungsten, copper, and a mixture thereof. In some embodiments, the stainless steel composition comprises an admixture of iron, chromium, and nickel, and comprises a nickel concentration of about 5 wt. % to about 20 wt. %. In some embodiments, the bonding composition can comprise or consist essentially of iron, chromium and nickel.

Stainless steel layers of the present disclosure can be free or substantially free of defects, such as cracks. Such cracks can penetrate into various depths of the layers and, in some cases, expose underlying layers. Layers of the present disclosure can have cracks at a density of at most about 50%, 40%, 30%, 20%, 15%, 10%, 9%, 8%, 7%, 6%, 5%, 4%, 3%, 2%, 1% (by surface area) in an area of at least about 1 μm², 5 μm², 10 μm², 20 μm², 30 μm², 40 μm², 50 μm², 100 μ², 500 μm², 1000 μm², 5000 μm², 10000 μm², 50000 μm², 100000 μm², or 500000 μm². In some instances, there are about 2 to 5 cracks in an area of about 80,000 μm².

In some embodiments, the stainless steel composition has a chromium concentration of about 16 wt. % to about 25 wt. %, and nickel concentration of about 6 wt. % to about 14 wt. %. In some embodiments, the stainless steel composition consists essentially of iron, chromium and nickel.

In some cases, the stainless steel composition has a chromium concentration of about 10.5 wt. % to about 18 wt. %. In some embodiments, the stainless steel composition consists essentially of iron and chromium and the bonding composition consists essentially of iron and chromium.

In some cases, the stainless steel coating includes the stainless steel region and the bonding region which can be positioned between the stainless steel region and the core region. The bonding region can have a thickness that is greater than 1 μm and less than the thickness of the stainless steel region. In some cases, the bonding region has a thickness of about 5 μm to about 200 μm, about 5 μm to about 100 μm, or about 10 μm to about 50 μm.

The bonding region can have a bonding composition, which can include an admixture of iron and chromium. In some cases, the bonding composition further includes a chromium concentration proximal to the stainless steel region that is approximately equal to the chromium concentration of the stainless steel region and having a chromium concentration proximal to the core region (e.g., that has less than about 5 wt. %, about 4 wt. %, about 3 wt. %, about 2 wt. %, about 1 wt. %, or about 0.5 wt. % chromium). That is, the chromium concentration can decrease through the boding region to a concentration that is less than half of the concentration in the stainless steel region (e.g., decreases to a concentration that is approximately equal to the concentration of chromium in the core region). The chromium concentration gradient in the bonding region can include a linear decrease in chromium concentration or a sigmoidal decrease in chromium concentration for example.

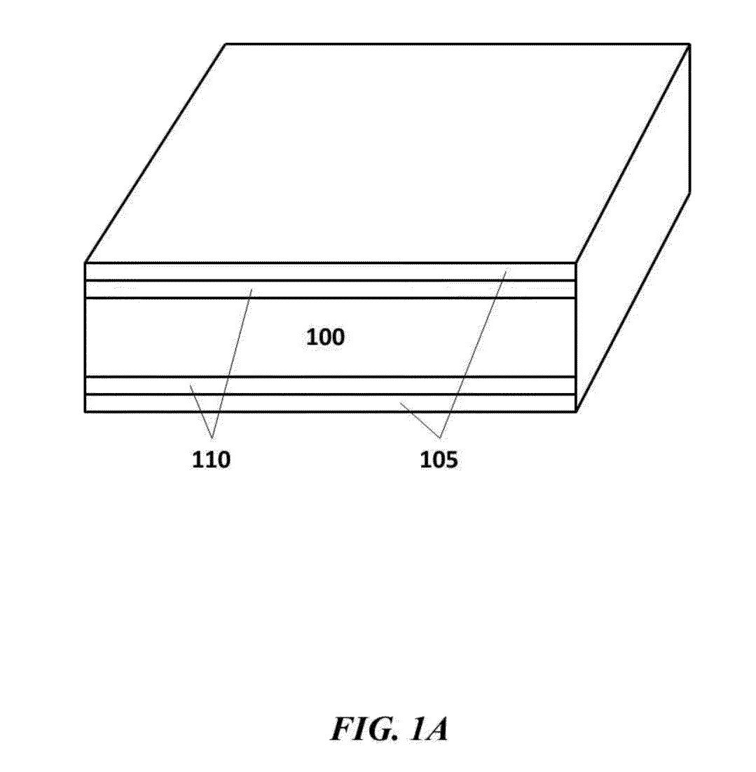

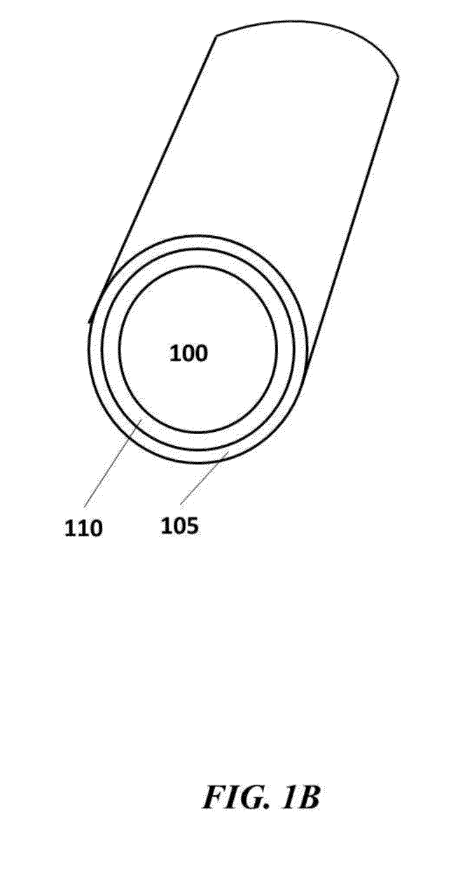

Another aspect of the present disclosure is a metal material that includes a plurality of regions. The material can be, without limitation, a metal sheet as shown in FIG. 1A or a metal rod as shown in FIG. 1B. The material can have a core region 100 that can be a relatively low-cost material such as carbon steel. The surface region of the material 105 can be stainless steel. A bonding region 110 can be located between the surface region and the core region. In some cases, the surface region has a thickness of about 1 μm to about 250 μm. The bonding region can have a thickness that is greater than 1 μm and less than the thickness of the surface region. The core region can have any thickness, including about 100 μm to about 4 mm, 10 mm, 5 cm, 10 cm, 20 cm, 50 cm, 100 cm or larger.

In some cases, the core region has a core composition that comprises at least 70 wt. % iron. In some instances, the iron concentration in the core region is greater than 75 wt. %, 85 wt. %, 90 wt. %, 95 wt. %, 98 wt. %, 99 wt. %, or 99.5 wt. %. In some cases, the core region is a carbon steel having a carbon concentration of less than about 0.5 wt. %. In some cases, the core region is a carbon steel having a carbon concentration of less than about 0.25 wt. %. In some embodiments, the core region is substantially free of chromium.

The surface region can have a stainless steel composition that is approximately consistent across the thickness of the region. These stainless steel composition can include an admixture of iron and chromium with a chromium concentration of about 10 wt. % to about 30 wt. %. In some cases, the chromium concentration can be about 10 wt. %, about 12 wt. %, about 14 wt. %, about 16 wt. %, about 18 wt. %, about 20 wt. %, about 22 wt. %, about 24 wt. %, about 26 wt. %, about 28 wt. %, or about 30 wt. %.

The bonding region can have a composition that includes an admixture of iron and chromium. The bonding region can have a chromium concentration proximal to the surface region that is approximately equal to the chromium concentration of the surface region. In some cases, the chromium concentration proximal to the core region is less than about 5 wt. %, about 4 wt. %, about 3 wt. %, about 2 wt. %, about 1 wt. %, or about 0.5 wt. % chromium. In some cases, the chromium concentration proximal to the core region is approximately equal to the chromium concentration in the core region (e.g., the bonding region has a chromium concentration gradient). The chromium concentration gradient in the bonding region can include a linear decrease in chromium concentration or a sigmoidal decrease in chromium concentration.

In some embodiments, the surface composition comprises an admixture of iron, chromium, and nickel, with a nickel concentration of about 5 wt. % to about 20 wt. %. The bonding composition can also include nickel.

In some embodiments, the surface composition comprises an admixture of iron, chromium, and a transition metal selected from the group consisting of nickel, molybdenum, titanium, niobium, tantalum, vanadium, tungsten, copper, and a mixture thereof. The bonding composition can also include the selected transition metal(s).

In some cases, the material that includes the regions described herein have a thickness of about 0.1 mm to about 4 mm, 10 mm, 5 cm, 10 cm, 20 cm, 50 cm, 100 cm or larger. The thickness can be the lesser of the height, length, or width of the material. For a typical sheet, the length and width can be multiple orders of magnitude greater than the height (or thickness). For example, the steel sheet can be a steel coil with a width of about 1 meter to about 4 meters and a length of greater than 50 meters.

In another aspect, described herein is a steel form that includes a brushed stainless steel surface carried by (i.e., disposed upon) a stainless steel region. In some embodiments, the stainless steel region can have a thickness of about 5 μm to about 200 μm, can have an approximately consistent stainless steel composition that includes an admixture of iron and chromium, and can have a chromium concentration of about 10 wt. % to about 30 wt. %. The stainless steel region can be carried by a bonding region. In some cases, the bonding region has a thickness of about 5 μm to about 200 μm but less than the thickness of the stainless steel region. The bonding region can metallurgically bond the stainless steel region to a core region. The core region can have a core composition that includes at least 85 wt. % iron. The bonding region can further include a bonding composition which includes an admixture of iron and chromium, and a bonding region concentration gradient that decreases from a chromium concentration proximal to the stainless steel region that is approximately equal to the chromium concentration of the stainless steel region to a chromium concentration proximal to the core region that is less than about 1 wt. %.

In some cases, the products are free of plastic deformation. As used herein, “plastic deformation” is the elongation or stretching of the grains in a metal or admixture brought about by the distortion of the metal or admixture. For example, cold rolled steel can display plastic deformation in the direction of the rolling. Plastic deformation in steel can be observable and quantifiable through the investigation of a cross-section of the steel. The products described herein can be substantially free of plastic deformation (e.g., the products include less than 15%, 10%, or 5% plastic deformation). In some cases, the products are essentially free of plastic deformation (e.g., the products include less than 1% plastic deformation). In some cases, the products described herein are free of plastic deformation (e.g., plastic deformation in the products is not observable by investigation of a cross section of the product). In some cases, the products described herein exhibit plastic deformation. The material can be full-hard (i.e., material that is highly stressed). In some embodiments, the substrate is used directly off of a cold mill (i.e., full-hard substrate). In some instances, full-hard substrate helps with the diffusion process, achieving rapid mixing during the re-crystallization process. The materials and methods described herein can use varying amounts of cold work (e.g., half-hard or quarter-hard substrate).

The products (e.g., which include a stainless steel layer or region carried by a steel or carbon steel substrate or core) can be manufactured by the low temperature deposition of chromium onto a starting substrate that becomes the core region. Available techniques for the deposition of chromium onto the starting substrate include, but are not limited to, physical vapor deposition, chemical vapor deposition, metal-organic chemical vapor deposition, sputtering, ion implantation, electroplating, electroless plating, pack cementation, the ONERA™ process, salt bath processes, chromium-cryolite processes, Alphatising process, or the like. In some instances, the chromium is deposited in a non-compact layer upon the starting substrate. In some cases, the chromium is deposited as a layer that consists essentially of chromium. In some cases, the chromium is deposited as an admixture of iron and chromium. In some instances, the chromium is deposited as an admixture of chromium and an element selected from the group consisting of nickel, molybdenum, titanium, niobium, tantalum, vanadium, tungsten, copper, and a mixture thereof. In some cases, a plurality of layers of chromium and an element selected from the group consisting of nickel, molybdenum, titanium, niobium, tantalum, vanadium, tungsten, copper, and a mixture thereof are deposited onto the starting substrate.

Following the deposition of the chromium onto the starting substrate, the deposited chromium and any other deposited metals can be heated to a temperature in a range of about 800° C. to about 1200° C., or about 1000° C. The stainless steel region can be comparable to a stainless steel composition designation selected from the group consisting of 403 SS, 405 SS, 409 SS, 410 SS, 414 SS, 416 SS, 420 SS, and 422 SS. The designation of the composition of the stainless steel layer can be affected by the concentration of trace elements in the carbon steel substrate (e.g., nickel, carbon, manganese, silicon, phosphorus, sulfur, and nitrogen), by the addition of one or more trace elements to the as deposited chromium, or by the addition of one or more trace elements by post treatment of the as-deposited chromium (e.g., by solution, deposition, or ion implantation methods).

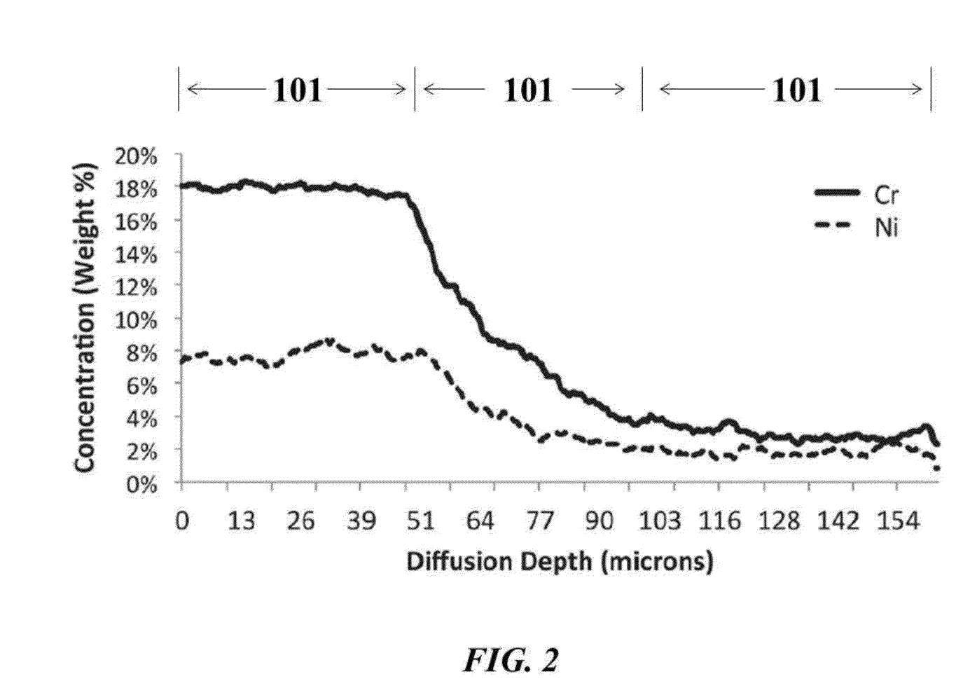

FIG. 2 shows an example of the approximate weight percentages of chromium and nickel as a function of depth (as measured by EDX) for a 300 series stainless steel surface metallurgically bonded to a carbon steel core. The stainless steel surface region is comparable to a stainless steel composition designation selected from the group consisting of 301 SS, 302 SS, 303 SS, and 304 SS. The designation of the composition of the stainless steel layer can be affected by the concentration of trace elements in the carbon steel substrate (e.g., carbon, manganese, silicon, phosphorus, sulfur, and nitrogen), by the addition of one or more trace elements to the as deposited chromium, or by the addition of one or more trace elements by post treatment of the as-deposited chromium (e.g., by solution, deposition, or ion implantation methods). Furthermore, the designation of the composition of the stainless steel is affected by the concentrations of the chromium and nickel in the stainless steel layer; these concentrations can be increased or decreased independently.

The determination of the thickness and composition of the stainless steel surface region, bonding region, and optionally the core region is determined by cross-sectional analysis of a sample of the products described herein. In some cases, the sample is defined by a 1 cm by 1 cm region of the face of the product. The sample can then be cut through the center of the 1 cm by 1 cm region and the face exposed by the cut can be polished on a Buehler EcoMet 250 ginder-polisher. In some cases, a five step polishing process includes 5 minutes at a force of 6 lbs with a Buehler 180 Grit disk, 4 minutes at a force of 6 lbs with a Hercules S disk and a 6 μm polishing suspension, 3 minutes at a force of 6 lbs with a Trident 3/6 μm disk and a 6 μm polishing suspension, 2 minutes at a force of 6 lbs with a Trident 3/6 μm disk and a 3 μm polishing suspension, and then 1.5 minutes at a force of 6 lbs with a microcloth disk and a 0.05 μm polishing suspension. The cut and polished face can then be in an instrument capable of energy-dispersive X-ray spectroscopy (EDX). The above provided grinding-polishing procedure may cross-contaminate distinct layers. The contamination can be consistent across the polished face. In some cases, a baseline measurement of a region that is free of a first element may display a greater than baseline concentration of the first element by EDX. The increase in the base line can be dependent on the area of the regions polished and the concentration of the respective elements in the polished faces.

### Iron Strike Plating on Passive Surfaces

A passive surface can be a surface upon in which additional metal layers do not form a metallurgical bond, such as metal surfaces that form an oxide layer when contacted with an atmosphere comprising oxygen. Examples of passive surfaces include chromium (Cr), titanium (Ti) and stainless steel (SS) surfaces. The present method can use a strong acid such as hydrochloric acid (HCl) to remove an oxide layer from a passive surface. In some cases, the acid is part of a solution that also includes a metal to be deposited onto the surface (e.g., electroplated).

Chromium is one example of a passive metal surface that can be used with the present methods, in some cases to deposit metal layers upon the chromium layer that can be heated to form a layer of stainless steel metallurgically bonded to a substrate.

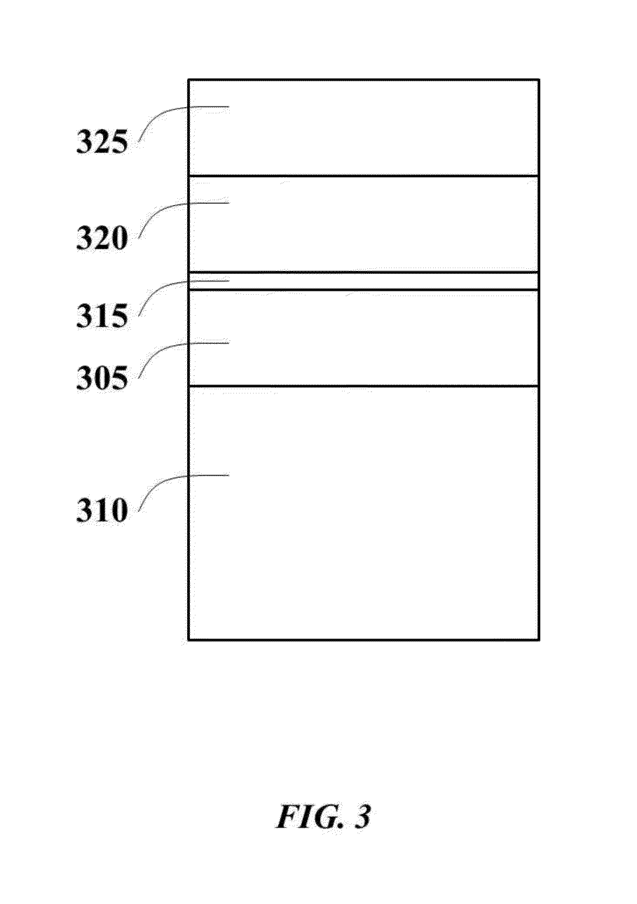

With reference to FIG. 3, a passive metal layer (e.g., chromium) 305 can be deposited on a substrate 310 (e.g., carbon steel). The methods described herein can be used to deposit a first metal layer 315 (sometimes referred to as a “flash” layer), such as iron upon the layer of chromium. The first metal layer can be metallurgically bonded to the chromium layer (e.g., atoms of the first metal layer and chromium atoms share electrons). The first metal layer can be thin (e.g., about 1 micrometer thick). Additional layers of metal 320, 325 can be deposited upon the first metal layer (e.g., using any method, in some cases the first metal layer does not form an oxide and/or is not a passive metal surface).

In some embodiments, the method is used to form a stainless steel layer metallurgically bonded to a substrate. Since stainless steel is an alloy comprising iron, chromium and nickel, with reference to FIG. 3, the layers are a carbon steel substrate 310, a layer of chromium 305, a flash layer of iron 315, an additional layer of iron 320 (e.g., electrodeposited on the flash layer 315), and a layer of nickel 325 (e.g., electrodeposited on the additional layer of iron). Stainless steel can be formed by heating the layers such that the metals diffuse amongst one another. The order of the layers in FIG. 3 is in contrast to some other methods and materials such as those described in U.S. Pat. No. 8,557,397, which is incorporated by reference in its entirety.

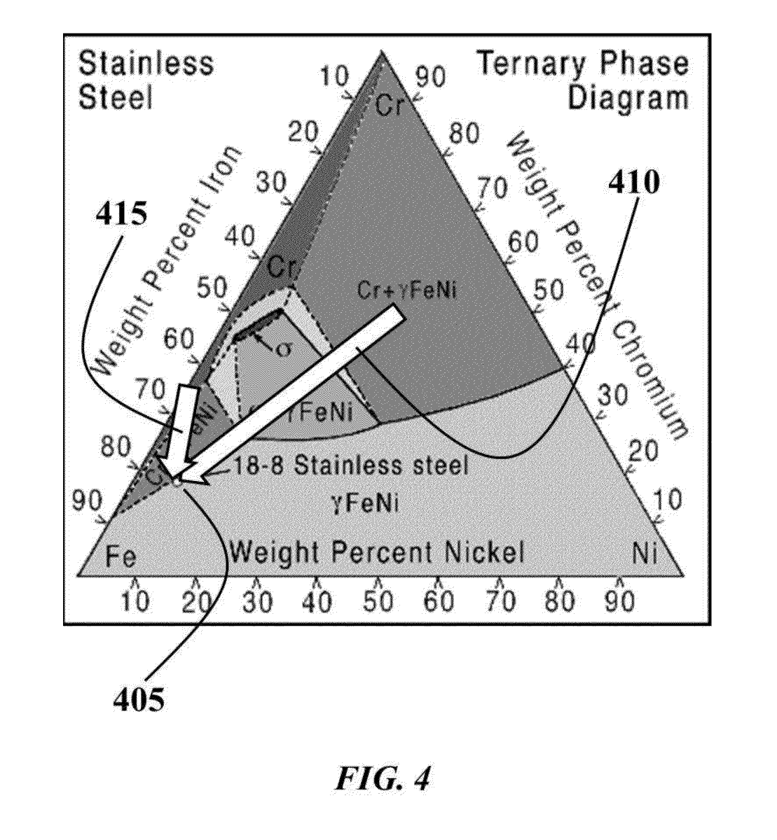

The order of the layers can allow for more rapid formation of the metallurgically bonded stainless steel layer. FIG. 4 is a ternary phase diagram of iron, chromium and nickel (the elements comprising stainless steel). The compositions of iron, chromium and nickel at any point on the stainless steel ternary phase diagram can be read from the diagram as follows: Instead of drawing one tie-line, as in a binary phase diagram, three lines are drawn, each parallel to a side of the triangle and going through the point in question. Extend the lines so they pass through an axis. To find the iron composition, the line drawn parallel to the axis opposite the iron vertex can be used. The percent iron is then read off the axis. For example, to determine the compositions of 18-8 stainless steel 405, draw these lines: (a) draw the first line to be parallel with the axis opposite the iron vertex, we find that the composition of iron is 74%, (b) next draw a line parallel with axis opposite the nickel vertex and read the composition of nickel to be 8%, and (c) draw a line parallel to the axis opposite the chromium vertex to see that there is 18% chromium. The point described is then referred to as 18-8 stainless steel, naming only the percentages of the chromium and the nickel with the iron content being dependent on the other two elements.

Various allotropes are shown in FIG. 4 as shaded regions within the phase diagram. The different allotropes have different stabilities and different rates of diffusion from each other. The time at which the layers mix to form a stainless steel layer upon heating can be dependent on the initial order and thickness of the metal layers deposited on the substrate as well as the allotropes that are traversed on the phase diagram to arrive at the final composition. In some cases, the desired final composition is not arrived at, for example if one of the intervening allotropes is stable and impedes further diffusion. The methods of the present disclosure allow for metal layers to be deposited on passive surfaces such as chromium. For example, when producing a metallurgically bonded layer of 18-8 stainless steel 405, the present methods allow for a shorter diffusional path, crossing fewer slow-diffusing allotropes 410 than is taught by competing methods 415.

In an aspect, the disclosure provides a method for plating iron on a chromium surface. The method can comprise a providing a metal substrate having a surface, contacting the surface with a solution comprising hydrochloric acid (HCl) and iron, and applying a voltage difference between the metal substrate and the solution. The iron can be an iron salt. In some cases, contacting the surface with the solution and applying the voltage are performed simultaneously. In some cases, the layer of iron adheres to the surface by metallic bonding.

The surface upon which additional metal layers are deposited can be a passive surface (e.g., having an oxide layer that prevents deposition of another metal layer). In some cases, the surface comprises chromium, titanium or stainless steel. In some instances, the surface comprises stainless steel. In some cases, the surface comprises at least about 80%, at least about 90%, at least about 95%, at least about 99%, or at least about 99.9% chromium as measured by x-ray photoelectron spectroscopy (XPS).

In some cases, the layer of metal (e.g., iron) deposited on the passive metal layer is thin. In some cases, the layer of iron has a thickness of about 0.1 micrometer (μm), about 0.5 μm, about 1 μm, about 1.5 μm, about 2 μm, about 3 μm, about 5 μm, or about 10 μm. In some instances, the layer of iron has a thickness of less than about 0.1 micrometer (μm), less than about 0.5 μm, less than about 1 μm, less than about 1.5 μm, less than about 2 μm, less than about 3 μm, less than about 5 μm, or less than about 10 μm.

The method can comprise depositing an additional layer of metal on the (first, strike) layer of iron. In some cases, an additional layer of iron is deposited on the layer of iron, and nickel is deposited on the additional layer of iron. In some cases, the additional layer of iron is deposited without contacting the metal substrate with the solution.

The method can further comprise heating the metal substrate, the layer of iron, and the additional layer of metal. The metal substrate, the layer of iron, and the additional layer of metal can be heated to any suitable temperature (e.g., such that the metals diffuse). In some cases, the metal substrate, the layer of iron, and the additional layer of metal are heated to a temperature of about 300° C., about 400° C., about 500° C., about 600° C., about 700° C., about 800° C., about 900° C., about 1000° C., about 1100° C., about 1200° C., about 1300° C., about 1400° C., or about 1500° C. In some cases, the metal substrate, the layer of iron, and the additional layer of metal are heated to a temperature of at least about 300° C., at least about 400° C., at least about 500° C., at least about 600° C., at least about 700° C., at least about 800° C., at least about 900° C., at least about 1000° C., at least about 1100° C., at least about 1200° C., at least about 1300° C., at least about 1400° C., or at least about 1500° C. In some cases, the metal substrate, the layer of iron, and the additional layer of metal are heated to a temperature of at most about 300° C., at most about 400° C., at most about 500° C., at most about 600° C., at most about 700° C., at most about 800° C., at most about 900° C., at most about 1000° C., at most about 1100° C., at most about 1200° C., at most about 1300° C., at most about 1400° C., or at most about 1500° C. In some cases, the metal substrate, the layer of iron, and the additional layer of metal are heated to a temperature of between about 930° C. and 1150° C.

Oil on the surface can impede the removal of the oxide layer and/or deposition of the iron strike layer. In some cases, the method further comprises removing an oil from the surface prior to contacting the surface with the solution. The oil can be removed with a solvent or with a caustic solution.

The surface can comprise an oxide (e.g., of chromium) and the solution can dissolve the oxide from the surface. The solution can include a strong acid, such as hydrochloric acid (HCl) in sufficient concentration to etch the oxide. In some cases, the concentration of hydrochloric acid (HCl) is about 1 Normal (N), about 2 N, about 3 N, about 4 N, about 5 N, about 6 N, about 7 N, about 8 N, about 9 N or about 10 N. In some cases, the concentration of hydrochloric acid (HCl) is at least about 1 Normal (N), at least about 2 N, at least about 3 N, at least about 4 N, at least about 5 N, at least about 6 N, at least about 7 N, at least about 8 N, at least about 9 N or at least about 10 N. In some cases, the concentration of hydrochloric acid (HCl) is at most about 1 Normal (N), at most about 2 N, at most about 3 N, at most about 4 N, at most about 5 N, at most about 6 N, at most about 7 N, at most about 8 N, at most about 9 N or at most about 10 N. In some cases, the concentration of hydrochloric acid (HCl) is between about 3 Normal (N) and 6 N.

The solution can have any amount of iron salt. In some cases, the solution comprises about 5, about 10, about 20, about 50, about 100, about 200, about 300, about 400, about 500, or about 600 grams of iron salt per liter of solution (g/L). In some cases, the solution comprises at least about 5, at least about 10, at least about 20, at least about 50, at least about 100, at least about 200, at least about 300, at least about 400, at least about 500, or at least about 600 grams of iron salt per liter of solution (g/L). In some cases, the solution comprises at most about 5, at most about 10, at most about 20, at most about 50, at most about 100, at most about 200, at most about 300, at most about 400, at most about 500, or at most about 600 grams of iron salt per liter of solution (g/L). In some cases, the solution comprises between about 50 and about 300 grams of iron salt per liter of solution (g/L).

The solution can be at any temperature. In some cases, the solution is at ambient temperature.

The iron salt can be any chemical form. In some instances, the iron salt comprises ferrous ions (Fe²⁺). In some cases, the iron salt is an iron halide. In some embodiments, the iron salt is a chloride or sulfate salt.

Applying the voltage can produce an electric current of any suitable magnitude (e.g., suitable to deposit iron on the surface). In some cases, the current is about 5, about 10, about 20, about 50, about 100, about 150, about 200, about 300, or about 500 amperes per square foot (Amp/ft²). In some cases, the current is at least about 5, at least about 10, at least about 20, at least about 50, at least about 100, at least about 150, at least about 200, at least about 300, or at least about 500 amperes per square foot (Amp/ft²). In some cases, the current is at most about 5, at most about 10, at most about 20, at most about 50, at most about 100, at most about 150, at most about 200, at most about 300, or at most about 500 amperes per square foot (Amp/ft²). In some cases, the current is between about 50 amperes per square foot (Amp/ft²) and about 200 Amp/ft².

The solution can be contacted to the surface and/or the voltage can be applied for any suitable time. In some cases, the solution is contacted to the surface and/or the voltage is applied for about 5, about 10, about 15, about 20, about 30, about 40, or about 60 seconds (s). In some instances, the solution is contacted to the surface and/or the voltage is applied for about 5, about 10, about 15, about 20, about 30, about 40, or about 60 minutes (min). In some cases, the solution is contacted to the surface and/or the voltage is applied for at least about 5, at least about 10, at least about 15, at least about 20, at least about 30, at least about 40, or at least about 60 seconds (s). In some instances, the solution is contacted to the surface and/or the voltage is applied for at least about 5, at least about 10, at least about 15, at least about 20, at least about 30, at least about 40, or at least about 60 minutes (min). In some cases, the solution is contacted to the surface and/or the voltage is applied for at most about 5, at most about 10, at most about 15, at most about 20, at most about 30, at most about 40, or at most about 60 seconds (s). In some instances, the solution is contacted to the surface and/or the voltage is applied for at most about 5, at most about 10, at most about 15, at most about 20, at most about 30, at most about 40, or at most about 60 minutes (min). In some cases, the solution is contacted to the surface and/or the voltage is applied for a period of time between about 20 seconds (s) and about 60 s.

The method for plating iron on a chromium surface described herein can be used to produce a material having a metal layer deposited on chromium. Thus, in another aspect, the disclosure provides a material comprising a metal substrate; a first metal layer comprising chromium deposited adjacent to the metal substrate; and a second metal layer comprising iron deposited on the first metal layer. The metal substrate can be carbon steel. In some cases, the first metal layer is deposited on the metal substrate. The metal substrate can be carbon steel. The second metal layer can be metallically bonded to the first metal layer.

The material can further comprise a third metal layer deposited on the second metal layer. The third metal layer can comprise iron. In some cases, the material further comprises a fourth metal layer deposited on the third metal layer. The fourth metal layer can comprise nickel.

The materials and/or methods described herein can be used to make a stainless steel surface diffusion bonded (or metallurgically bonded) to a metal substrate. Thus, in another aspect, the disclosure provides a method that can comprise providing a metal substrate, depositing a layer of chromium adjacent to the metal substrate, depositing a layer of iron adjacent to the layer of chromium, depositing a layer of nickel adjacent to the layer of iron and heating the layers of chromium, iron and nickel to form a layer of stainless steel diffusion bonded to the metal substrate. The layers can be deposited using electro-deposition, vapor deposition, or any combination thereof.

In some embodiments, the layer of chromium is deposited on the metal substrate, the layer of iron is deposited on the layer of chromium and/or the layer of nickel is deposited on the layer of iron. In some cases, additional layer(s) are disposed between any two adjacent metal layers.

In some cases, the layer of iron comprises at least two layers of iron (e.g., a thin strike layer and a second iron layer deposited on the strike layer). The method for depositing iron can comprise depositing a first layer of iron on the chromium and depositing an additional layer of iron on the first layer of iron. In some cases, the first layer of iron has a thickness of less than about 1 micrometer (μm).

The first layer of iron can be deposited by contacting the chromium with a solution comprising hydrochloric acid (HCl) and iron, where the iron is an iron salt, and applying a voltage difference between the metal substrate and the solution, where the first layer of iron is deposited on the chromium.

The layers of chromium, iron and nickel can be heated (e.g., to a temperature between about 930° C. and 1150° C.) for any suitable period of time. In some cases, the layers of chromium, iron and nickel are heated for about 1, about 2, about 5, about 10, about 15, about 20, about 30, about 40, or about 50 hours (h). In some cases, the layers of chromium, iron and nickel are heated for at least about 1, at least about 2, at least about 5, at least about 10, at least about 15, at least about 20, at least about 30, at least about 40, or at least about 50 hours (h). In some cases, the layers of chromium, iron and nickel are heated for at most about 1, at most about 2, at most about 5, at most about 10, at most about 15, at most about 20, at most about 30, at most about 40, or at most about 50 hours (h). In some cases, the layers of chromium, iron and nickel are heated for between about 15 hours (h) and about 20 h.

Upon heating, the metals can diffuse to form a layer of stainless steel metallurgically bonded to the substrate. The layer of stainless steel can have any suitable thickness including about 50, about 100, about 150, about 200, about 250, about 300, about 400, about 500, or about 1000 microns (μm) thick. The layer of stainless steel can be at least about 50, at least about 100, at least about 150, at least about 200, at least about 250, at least about 300, at least about 400, at least about 500, or at least about 1000 microns (μm) thick.

### Properties of the Materials

In an aspect of the present disclosure, a material comprises an alloyed metal layer having an alloying agent, the alloyed metal layer being coupled to a steel substrate with the aid of a diffusion layer between the alloyed metal layer and the steel substrate. In some cases, the amount of alloying agent in the diffusion layer changes with depth at a rate between about −0.01% per micrometer and −5.0% per micrometer.

The amount of alloying agent in the diffusion layer can change with depth at any suitable rate. In some cases, the amount of alloying agent in the diffusion layer as measured by x-ray photoelectron spectroscopy changes with depth at a rate of about −0.001%, about −0.005%, about −0.01%, about −0.05%, about −0.1%, about −0.5%, about −1%, or about −5% per micrometer. In some cases, the amount of alloying agent changes with depth at a rate of at most about −0.001%, at most about −0.005%, at most about −0.01%, at most about −0.05%, at most about −0.1%, at most about −0.5%, at most about −1%, or at most about −5% at most about per micrometer. In some cases, the amount of alloying agent in the diffusion layer changes with depth at a rate between about −0.05% per micrometer and −1.0% per micrometer. In some cases, the amount of alloying agent in the diffusion layer changes with depth at a rate between about −0.15% per micrometer and −0.60% per micrometer. In some cases, the depth is measured from an exterior surface of the alloyed metal layer.

In some cases, the diffusion layer provides a metallurgical bond between the alloyed metal layer and the low-carbon steel substrate. In some cases, the alloyed metal is stainless steel.

The alloying agent can be any suitable material. In some cases, the alloying agent comprises chromium, nickel, iron, or any combination thereof. The steel substrate can be any suitable material. In some cases, the steel substrate is stainless steel, low-carbon steel or carbon steel.

The alloyed metal layer can have any suitable thickness. In some cases, the thickness of the alloyed metal layer is about 500, about 300, about 200, about 100 or about 50 micrometers. In some cases, the thickness of the alloyed metal layer is at least about 500, at least about 300, at least about 200, at least about 100 or at least about 50 micrometers. In some cases, the thickness of the alloyed metal layer is at most about 500, at most about 300, at most about 200, at most about 100 or at most about 50 micrometers.

In an aspect, a material of the disclosure comprises an outer metal layer metallurgically bonded to a steel substrate, the material having a high durability as measured by contact mode atomic force microscopy (AFM). Under static mode AFM, static tip deflection can be used as a feedback signal. Because the measurement of a static signal is prone to noise and drift, low stiffness cantilevers can be used to boost the deflection signal. However, close to the surface of the material, attractive forces can be quite strong, causing the tip to “snap-in” to the surface. Static mode AFM can be done in contact where the overall force is repulsive. In contact mode AFM, the force between the tip and the surface is kept constant during scanning by maintaining a constant deflection.

In some cases, the material of the disclosure passes durability tests for the American Society for Testing and Materials (ASTM). ASTM's durability of material standards can provide procedures for carrying out environmental exposure tests to determine the durability, service life, and weathering behavior of certain materials. These tests can be conducted to examine and evaluate the algal resistance, light exposure behavior, activation spectrum, spectral irradiance and distribution, and microbial susceptibility of materials, which can include metals, polymeric materials, glass, and plastic films. These standards can also present the recommended calibration and operational procedures for the instruments used in conducting such tests such as pyrheliometer, UV radiometer and spectroradiometer, pyranometer, carbon arc, fluorescent, and xenon arc light apparatuses, metal black panel and white panel temperature devices, and sharp cut-on filter. These durability of material standards can be useful to manufacturers and other users concerned with such materials and products in understanding their resilience and stability mechanism.

The outer metal layer can be any suitable material. In some cases, the outer metal layer is steel. In some instances, the outer metal layer is stainless steel. In some cases, outer metal layer comprises chromium, nickel, or a combination thereof

The outer metal layer can have any suitable thickness. In some cases, the thickness of the outer metal layer is about 500, about 300, about 200, about 100 or about 50 micrometers. In some cases, the thickness of the outer metal layer is at least about 500, at least about 300, at least about 200, at least about 100 or at least about 50 micrometers. In some cases, the thickness of the outer metal layer is at most about 500, at most about 300, at most about 200, at most about 100 or at most about 50 micrometers.

In some cases, the outer metal layer is configured such that it does not become dislodged from the steel substrate when contacted by the AFM. The steel substrate can be a low-carbon steel or a carbon steel. In some cases, the metallurgical bond comprises a diffusion layer (e.g., such that there is not a discontinuity of material composition where the layers come into contact).

In an aspect of the present disclosure, a material comprises an outer metal layer metallurgically bonded to a steel substrate, where the material corrodes at a rate of at most about 1 nanometer per hour when exposed to an oxidizing environment or corrosive environment. An oxidizing environment can include one or more oxidizing agents. An oxidizing agent can include oxygen (O₂), water (H₂O) and/or hydrogen peroxide (H₂O₂). In some cases, the material has no discontinuity between the outer metal layer and the steel substrate. In some cases, the material passes the ASTM B117 test (e.g., that includes a salt spray and condensing humidity).

The oxidizing environment can be any suitable environment (e.g., comprising air, water, chloride ions and/or peroxide).

In some cases, an oxidizing or corrosive environment is at a temperature of at least about 1° C., 5° C., 10° C., 15° C., 20° C., 25° C., 30° C., 40° C., 50° C., 60° C., 70° C., 80° C., 90° C., or 100° C. The oxidizing or corrosive environment can be at a pressure of at least 1 atmosphere (atm), 2 atm, 3 atm, 4 atm, 5 atm, 6 atm, 7 atm, 8 atm, 9 atm, 10 atm, 20 atm, 30 atm, 40 atm, 50 atm, 60 atm, 70 atm, 80 atm, 90 atm, or 100 atm.

In some examples, a corrosive environment includes an acid. Examples of acids include sulfuric acid, sulfurous acid, hydrochloric acid and hydrofluoric acid. In other examples, the corrosive environment includes a base. Examples of bases include calcium oxide, magnesium oxide, potassium hydroxide, sodium hydroxide, calcium hydroxide, calcium carbonate, potassium carbonate, sodium carbonate, sodium sesquicarbonate, sodium silicate, calcium silicate, magnesium silicate or calcium aluminate.

The material can corrode at any suitably low rate. In some cases, the material corrodes at a rate of at most about 0.01, at most about 0.05, at most about 0.1, at most about 0.5, at most about 1, or at most about 5 nanometers per hour when exposed to an oxidizing or corrosive environment. In some cases, the material corrodes at a rate of about 0.01, about 0.05, about 0.1, about 0.5, about 1, or about 5 nanometer per hour when exposed to an oxidizing or corrosive environment. In some cases, the oxidizing or corrosive environment comprises 5% sodium chloride (NaCl) dissolved in a 3% hydrogen peroxide (H₂O₂) water mixture at room temperature.

The material can last a long time. In some cases, the surface of the material is corroded by about 0.1, about 0.5, about 1, about 5, about 10, or about 50 micrometers after one year. In some cases, the surface of the material is corroded by at most about 0.1, at most about 0.5, at most about 1, at most about 5, at most about 10, or at most about 50 micrometers after one year.

In an aspect of the present disclosure, a material comprises a stainless steel layer metallurgically bonded to a steel substrate, where the material has a corrosion resistance of at least about 1 year under the copper acetic acid spray (CASS) test. Conditions for the CASS test are known in the art and include mixtures of acetic acid and copper chloride. Another suitable testing procedure is the acetic acid test (ASS). In some cases, the material passes the ASTM B117 test (e.g., that includes a salt spray and condensing humidity).

The material can have a high resistance to corrosion. In some cases, the material has a corrosion resistance of about 5, about 10, about 15, about 20, about 25, or about 30 years under the copper acetic acid spray (CASS) test. In some cases, the material has a corrosion resistance of at least about 5, at least about 10, at least about 15, at least about 20, at least about 25, or at least about 30 years under the copper acetic acid spray (CASS) test.

The stainless steel layer can have any suitable thickness. In some cases, the thickness of the stainless steel layer is about 500, about 300, about 200, about 100 or about 50 micrometers. In some cases, the thickness of the stainless steel layer is at least about 500, at least about 300, at least about 200, at least about 100 or at least about 50 micrometers. In some cases, the thickness of the stainless steel layer is at most about 500, at most about 300, at most about 200, at most about 100 or at most about 50 micrometers.

In an aspect of the present disclosure, a metal-containing object comprises a steel core at least partially coated with an alloyed metal layer having an alloying agent, where the alloyed metal layer has a thickness of less than 500 micrometers, and where the concentration of alloying agent has a maximum concentration in the metal object and the concentration of the alloying agent in the alloyed metal layer decreases by no more than 20% compared with the maximum concentration. In some cases, the metal-containing object further comprises a diffusion layer between the alloyed metal layer and the steel core. In some instances, the diffusion layer metallurgically bonds the alloyed metal layer with the steel core. In some cases, there is not a discontinuity between the alloyed metal layer and the steel core.

The concentration of the alloying agent can decrease to any suitable value. In some embodiments, the concentration of alloying agent decreases to substantially zero in the diffusion layer. In some cases, the concentration of the alloying agent in the alloyed metal layer decreases by about 5%, about 10%, about 20%, about 30%, about 40%, about 50%, about 60%, about 70%, about 80%, about 90%, or about 95% compared with the maximum concentration. In some cases, the concentration of the alloying agent in the alloyed metal layer decreases by no more than about 5%, no more than about 10%, no more than about 20%, no more than about 30%, no more than about 40%, no more than about 50%, no more than about 60%, no more than about 70%, no more than about 80%, no more than about 90%, or no more than about 95% compared with the maximum concentration. In some cases, the concentration of the alloying agent in the alloyed metal layer decreases by at least about 5%, at least about 10%, at least about 20%, at least about 30%, at least about 40%, at least about 50%, at least about 60%, at least about 70%, at least about 80%, at least about 90%, or at least about 95% compared with the maximum concentration.

In an aspect of the present disclosure, a metal-containing object comprises an alloying agent, where the alloying agent has a concentration of at least 10% (w/w) at a depth of less than or equal to 30 micrometers from the surface of the object, and where the alloying agent has a concentration of at most 6% (w/w) at a depth of greater than 150 micrometers from the surface of the object. In some cases, the alloying agent has a concentration of at least 15% (w/w) at a depth of less than or equal to 50 micrometers from the surface of the object. In some cases, the alloying agent has a concentration of at least 10% (w/w) at distances less than or equal to 75 micrometers from the surface of the object. In some cases, the alloying agent has a concentration of at most 4% (w/w) at a depth of greater than 150 micrometers from the surface of the object.

The materials described here can be formed into any suitable object or product. Non-limiting examples include wire, rods, tubes (having an inner and/or outer diameter), formed parts, metal roofing material, electronic devices, cooking appliances, automobile parts, sporting equipment, bridges, buildings, structural steel members, construction equipment, roads, railroad tracks, ships, boats, trains, airplanes, flooring material, and the like.

The wire, rods, tubes, structural steel members, etc. can be used in any suitable application. In some cases, the materials described herein have properties, a cost and/or form factors that allow for new applications not practical with previous materials. For example, lashing wire can be used to connect wires (e.g., telephone and cable television wires) to support cables. Lashing wire can be stainless steel (200, 300 or 400 series) wire with a final diameter of 0.038 to 0.045 inches. The lashing wire can have a soft core with abrasion and corrosion resistance on the surface. In another example, the wire can be coated with nickel (Ni) and/or copper (Cu) to prevent bio-fouling (e.g., for use in fish farming). The wire can have a 50 micrometers thick coating on a 2 to 2.5 millimeter diameter 304 stainless steel core wire substrate.

In an aspect, described herein are materials having spatial segregation of different metal compositions in different portions of the material (e.g., a core portion and a metallurgically bonded surface layer). The spatially segregated materials can have different properties than can be achieved with a monolithic metal. For example, the spatially segregated material can have any combination of electrical, magnetic, corrosion resistance, scratch resistance, anti-microbial, heat transfer, and mechanical properties. In some cases, anti-microbial properties can be achieved by adding copper, aluminum or silver to steel surfaces. In some cases, scratch resistance can be achieved on light weight and/or soft alloys by doping with aluminum, magnesium or titanium surfaces with tungsten or cobalt. The cost of the material can be reduced by eliminating some of the alloying elements that would otherwise be in the bulk of the material.

In some cases, the materials described herein are used in heat exchangers. The improved heat exchangers described herein can have improved corrosion resistance and thermal (heat transfer) properties by alloying copper and nickel onto steel surfaces.

In some cases, the materials described herein are used in motors or transformers. The improved motors and transformers described herein can have improved performance by enriching steel surfaces with silicon and/or cobalt.

In some cases, the materials described herein are used as catalysts. The improved catalysts described herein can have reduced costs by embedding catalytic particles in steel surfaces.

In an aspect, described herein are methods for producing metal materials comprising purchasing a metal substrate, forming a metallurgically bonded layer on the metal substrate, and selling the metal material comprising the metal substrate and the metallurgically bonded layer. In some cases, the method produces the metal material for lower cost than a metal material having the composition of the metallurgically bonded layer throughout the entire material.

Another aspect provides a method for forming a material stack. The method can include providing a metal substrate, such as carbon or low-carbon steel substrate. The material stack can be formed by depositing a first metal layer (e.g., comprising chromium) adjacent to (e.g., onto) the metal substrate and then depositing a second metal layer (e.g., comprising iron) on the first metal layer. The second layer may be metallically bonded to the first layer. A third metal layer can be added to the material stack by depositing the third metal layer (e.g., comprising iron) on the second metal layer. Where the material stack comprises a third metal layer, a fourth metal layer (e.g., comprising nickel) can be added to the material stack by depositing the fourth metal layer on the third metal layer. In some cases, the material stack can be formed without any annealing. Moreover, once formed, the material stack can be annealed to, for example, further bond one or more of its layers together.

The first metal layer may comprise at least about 70%, at least about 75%, at least about 80%, at least about 85%, at least about 90%, at least about 91%, at least about 92%, at least about 93%, at least about 94%, at least about 95%, at least about 96%, at least about 97%, at least about 98%, at least about 99% or more chromium as measured by XPS. In some examples, the first metal layer comprises at least about 95% chromium as measured by XPS. The second metal layer can have any suitable thickness. For example, the thickness of the second layer can be less than about 20 micrometers, 15 micrometers, 10 micrometers, 8 micrometers, 7 micrometers, 6 micrometers, 5 micrometers, 4 micrometers, 3 micrometers, 2 micrometers, 1 micrometer, 0.5 micrometer, 0.1 micrometer or less.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives, modifications, variations or equivalents to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. A method for plating iron on a chromium surface, the method comprising:
(a) providing a metal substrate having a surface;
(b) contacting the surface with a solution comprising hydrochloric acid (HCl) and iron, wherein the iron is provided as an iron salt; and
(c) applying a voltage difference between the metal substrate and the solution to deposit a layer of iron from the iron salt onto the surface.

2. The method of claim 1, wherein the surface comprises chromium, titanium, or stainless steel.

3. The method of claim 1, wherein the surface is a passive surface.

4. The method of claim 1, wherein the surface comprises at least about 95% chromium as measured by x-ray photoelectron spectroscopy (XPS).

5. The method of claim 1, wherein the metal substrate comprises stainless steel and/or carbon steel.

6. The method of claim 1, wherein the layer of iron has a thickness of less than about 1 micrometer (μm).

7. The method of claim 1, further comprising depositing an additional layer of metal on the layer of iron.

8. The method of claim 7, wherein an additional layer of iron is deposited on the layer of iron, and nickel is deposited on the additional layer of iron.

9.-16. (canceled)

17. The method of claim 1, wherein the iron salt comprises ferrous ions (Fe²⁺).

18. The method of claim 1, wherein the iron salt comprises an iron halide.

19. The method of claim 1, wherein the iron salt comprises a chloride or sulfate salt.

20. (canceled)

21. The method of claim 1, wherein applying the voltage in (c) produces an electric current between about 50 amperes per square foot (Amp/ft²) and about 200 Amp/ft².

22. (canceled)

23. (canceled)

24. The method of claim 1, wherein (b) and (c) are performed simultaneously.

25. A method for making a stainless steel surface diffusion bonded to a metal substrate, the method comprising:
(a) providing a metal substrate;
(b) depositing a layer of chromium adjacent to the metal substrate;
(c) depositing at least one layer of iron adjacent to the layer of chromium;
(d) depositing a layer of nickel adjacent to the layer of iron; and
(e) heating the layers of chromium, iron and nickel to form a layer of stainless steel diffusion bonded to the metal substrate.

26. The method of claim 25, wherein the layer of chromium is deposited on the metal substrate.

27. The method of claim 25, wherein the layer of iron is deposited on the layer of chromium.

28. The method of claim 25, wherein the layer of nickel is deposited on the layer of iron.

29. The method of claim 25, wherein the at least one layer of iron comprises at least two layers of iron.

30. The method of claim 29, wherein (c) comprises (i) depositing a first layer of iron on the chromium and (ii) depositing an additional layer of iron on the first layer of iron.

31. The method of claim 30, wherein the first layer of iron has a thickness of less than about 1 micrometer (μm).

32. The method of claim 30, wherein the first layer of iron is deposited by contacting the chromium with a solution comprising hydrochloric acid (HCl) and iron, wherein the iron is an iron salt, and applying a voltage difference between the metal substrate and the solution, whereby the first layer of iron is deposited on the chromium.

33. The method of claim 25, wherein (b)-(d) are performed using electro-deposition and/or vapor deposition.

34.-36. (canceled)

37. The method of claim 25, wherein the layer of stainless steel is at least about 250 microns (μm) in thickness.

38. A method for forming a material stack, comprising:
(a) providing a metal substrate, which metal substrate is a carbon or low-carbon steel substrate;
(b) depositing a first metal layer comprising chromium adjacent to the metal substrate; and
(c) depositing a second metal layer comprising iron on the first metal layer to form the material stack,
wherein (a)-(c) are performed without annealing.

39.-47. (canceled)
